(19) United States
(12) Patent Application Publication
(10) Pub. No.: US 2026/0060154 A1
(43) Pub. Date: Feb. 26, 2026

(54) METHOD FOR MANUFACTURING SEMICONDUCTOR BONDING STRUCTURE

(71) Applicant: United Microelectronics Corp., Hsinchu (TW)

(72) Inventors: Chiao-Yi TENG, Taichung City (TW); Yang-Ju LU, Changhua County (TW); Chih-Yueh LI, Taipei City (TW); Kun-Ju LI, Tainan City (TW); Jhih-Yuan CHEN, Kaohsiung City (TW); Ang CHAN, Taipei City (TW)

(21) Appl. No.: 18/900,981

(22) Filed: Sep. 30, 2024

(30) Foreign Application Priority Data
Aug. 26, 2024 (TW) 113132061

(51) Int. Cl. H01L 23/00

(52) U.S. Cl. CPC H01L 24/80; H01L 24/08; H01L 2224/08145; H01L 2224/80006; H01L 2224/80895; H01L 2224/80896

(57) ABSTRACT

A method for manufacturing a semiconductor bonding structure is provided. The method includes forming a first semiconductor structure, forming a second semiconductor structure and hybrid bonding the first semiconductor structure and the second semiconductor structure. The step of forming the first semiconductor structure includes introducing boron into a first substrate to form an doped region in the first substrate, forming a first dielectric layer above the first substrate, and forming a first conductive pad in the first dielectric layer. The step of forming a second semiconductor structure includes forming a second dielectric layer above a second substrate, and forming a second conductive pad in the second dielectric layer. The first conductive pad is attached to the second conductive pad. The first dielectric layer is attached to the second dielectric layer.

This application claims the benefit of Taiwan application Serial No. 113132061, filed Aug. 26, 2024, the subject matter of which is incorporated herein by reference.

### BACKGROUND

### Technical Field

The disclosure relates to a semiconductor manufacturing method, and more particularly relates to a method for manufacturing a semiconductor bonding structure.

### Description of the Related Art

wafer-to-wafer bonding processes can be used to bond multiple wafers to obtain a semiconductor device structure, and is one of the key technologies to achieve high-density integration of three-dimensional integrated circuits. The existing wafer bonding process usually includes steps of alignment, bonding, etching, and polishing, and requires the use of tetramethylammonium hydroxide (TMAH). However, tetramethylammonium hydroxide is toxic and cost for treating tetramethylammonium hydroxide is high, and structural damages may easily occur in the existing wafer bonding process.

### SUMMARY

According to some embodiments, a method for manufacturing a semiconductor bonding structure is provided. The method includes forming a first semiconductor structure, forming a second semiconductor structure and hybrid bonding the first semiconductor structure and the second semiconductor structure. The step of forming the first semiconductor structure includes introducing boron into a first substrate to form an doped region in the first substrate, forming a first dielectric layer above the first substrate, and forming a first conductive pad in the first dielectric layer. The step of forming a second semiconductor structure includes forming a second dielectric layer above a second substrate, and forming a second conductive pad in the second dielectric layer. The first conductive pad is attached to the second conductive pad. The first dielectric layer is attached to the second dielectric layer.

The above and other embodiments of the disclosure will become better understood with regard to the following detailed description of the non-limiting embodiment(s). The following description is made with reference to the accompanying drawings.

### BRIEF DESCRIPTION OF THE DRAWINGS

FIGS. 1 to 7 illustrate a method for manufacturing a semiconductor bonding structure according to an embodiment of the present disclosure.

### DETAILED DESCRIPTION

Various embodiments will be described more fully hereinafter with reference to accompanying drawings. For clarity, the components may not be drawn to scale. The specification and the drawings are to be regarded as an illustrative sense rather than a restrictive sense. The illustration uses the same/similar reference numerals to indicate the same/similar elements. Moreover, use of ordinal terms such as “first”, “second”, “third”, etc., in the specification and claims to modify an element does not by itself imply any priority, precedence, or order of one claim element over another, but are used merely as labels to distinguish one claim element having a certain name from another element having the same name (but for use of the ordinal term) to distinguish the claim elements.

As used in the specification and the appended claims, spatial relation terms such as “on”, “above”, “over”, “upper,” “top”, “below”, “beneath”, “under”, “lower” and “bottom” be used to describe the relative spatial relations or positional relations between one element(s) and another element(s) as illustrated in the drawings, and these spatial relations or positional relations, unless specified otherwise, can be direct or indirect. The spatial relation terms are intended to encompass different orientations of structures in addition to the orientation depicted in the drawings. The structure can be inverted or rotated by various angles, and the spatial relation descriptions used herein can be interpreted accordingly. As used in the specification and the appended claims, the singular forms “a,” “an,” and “the” are intended to include the plural forms as well, unless the context clearly indicates otherwise. As used in the specification and the appended claims, the term “and/or” includes any and all combinations of one or more of the associated listed items.

Additionally, the term “electrically connected” used in the specification and claims can refer to an ohmic contact between elements, or current passing through elements, or an operational relation between elements. The operational relation may mean, for example, that one element is used to drive another element, but current may not flow directly between these two elements. As used in the specification and the appended claims, term “deposition” includes, but is not limited to, chemical vapor deposition (CVD), physical vapor deposition (PVD), atomic layer deposition (ALD) and epitaxial growth. Depending on the type of material to be formed, a person of ordinary skill in the art can select an appropriate technology for forming the material.

As used in the specification and the appended claims, term “etching” includes, but is not limited to, dry etching and wet etching. As used in the specification and the appended claims, term “polishing process” includes, but is not limited to, a mechanical polishing process, such as a grinding process with a polishing wheel, a chemical-mechanical polishing (CMP) process and n ion milling process. The terms “etching” and “polishing process” used in the specification and the appended claims may replace with each other, and a person of ordinary skill in the art can select an appropriate removal technology depending on the structure and material.

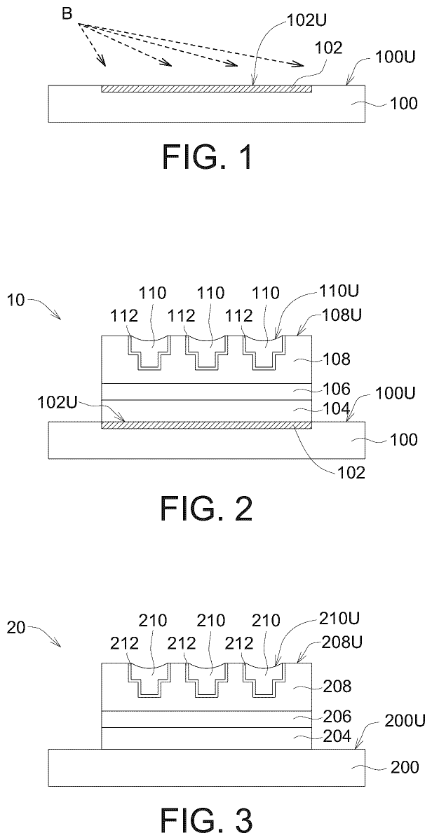

FIGS. 1 to 7 illustrate a method for manufacturing a semiconductor bonding structure according to an embodiment of the present disclosure.

Referring to FIG. 1, FIG. 1 shows a schematic view of the structure at one stage of the method for manufacturing the semiconductor bonding structure. A substrate 100 is provided. The substrate 100 is a semiconductor substrate. The semiconductor substrate can include or be made of a semiconductor material, such as silicon, germanium, gallium arsenide, silicon carbide, and gallium nitride. In an embodiment, the substrate 100 includes or is made of monocrystalline silicon. In an embodiment, the substrate 100 is a silicon wafer. In an embodiment, the substrate 100 is a blanket wafer.

Boron (boron atoms or boron ions) is introduced into the substrate 100 to form a doped region 102 in the substrate 100. Boron is implanted at a surface 100U of the substrate 100. Boron is implanted at the entire surface 100U or a portion of the surface 100U of the substrate 100. The doped region 102 can be a boron-doped semiconductor material. In an embodiment, the doped region 102 is boron-doped silicon or boron-doped monocrystalline silicon. In an embodiment, boron is introduced into the substrate 100 to form the doped region 102 through a thermal diffusion process or an ion implantation process. The concentration of boron in the doped region 102 can be any value. For example, the concentration of boron in the doped region 102 can be between 2×10¹⁹ atoms/cm³ and 5×10²¹ atoms/cm³. For example, in the case where the substrate 100 is made of monocrystalline silicon, the concentration of boron in the doped region 102 can be about 4×10²⁰ atoms/cm³. The thickness of the doped region 102 can range from about 5 nanometers to about 100 nanometers, but the present disclosure is not limited thereto. The surface 102U of the doped region 102 may be coplanar with the surface 100U of the substrate 100.

Referring to FIG. 2, FIG. 2 shows a schematic view of the structure at one stage of the method for manufacturing the semiconductor bonding structure. A pad oxide layer 104, a device layer 106 and a dielectric layer 108 are formed above the substrate 100, and a conductive pad 110 and a barrier layer 112 are formed in the dielectric layer 108, thereby forming a semiconductor structure 10. The pad oxide layer 104 is between the doped region 102 and the device layer 106. The pad oxide layer 104 is between the doped region 102 and the dielectric layer 108. The device layer 106 is between the pad oxide layer 104 and the dielectric layer 108. The barrier layer 112 is between the conductive pad 110 and the dielectric layer 108. The barrier layer 112 may cover a side surface and a bottom surface of the conductive pad 110. The device layer 106 may include active devices, such as transistors and silicon controlled rectifiers, and/or passive devices, such as resistors, capacitors, and inductors. The pad oxide layer 104 may include an oxide material, such as silicon oxide (SiOₓ). The dielectric layer 108 may include a dielectric material, such as silicon oxide (SiOₓ), silicon nitride (SiNₓ), and silicon carbonitride (SiCₓN_{y}). The barrier layer 112 may include a metal barrier material, such as tantalum, tantalum nitride, cobalt, ruthenium, titanium, and titanium nitride. The conductive pad 110 may include a conductive material, such as copper, aluminum, tungsten, tantalum, titanium, titanium nitride, tantalum nitride, and any combination thereof. The active devices and/or passive devices in the device layer 106 may be electrically connected to the conductive pad 110 and the barrier layer 112.

In an embodiment, the pad oxide layer 104 can be formed on the surface 102U of the doped region 102 through a deposition process. The device layer 106 can be formed on the pad oxide layer 104 through a deposition process and an etching process. The dielectric layer 108 can be formed on the device layer 106 through a deposition process. A portion of the dielectric layer 108 can be removed through an etching process, and the conductive pad 110 and the barrier layer 112 are formed in the dielectric layer 108 through a deposition process. The upper surface 110U of the conductive pad 110 may be recessed inward, or alternatively, the upper surface 110U of the conductive pad 110 may be substantially flat and coplanar with the upper surface 108U of the dielectric layer 108. The device layer 106 may be formed in the front-end-of-line (FEOL) process and the back-end-of-line (BEOL) process of the semiconductor manufacturing process.

Referring to FIG. 3, FIG. 3 shows a schematic view of the structure at one stage of the method for manufacturing the semiconductor bonding structure. A semiconductor structure 20 is formed. The formation of the semiconductor structure 20 may include the following steps. A substrate 200 is provided. A pad oxide layer 204, a device layer 206 and a dielectric layer 208 are formed above the substrate 200, and a conductive pad 210 and a barrier layer 212 are formed in the dielectric layer 208, thereby forming the semiconductor structure 20. The pad oxide layer 204 is between the substrate 200 and the dielectric layer 208. The device layer 206 is between the pad oxide layer 204 and the dielectric layer 208. The barrier layer 212 is between the conductive pad 210 and the dielectric layer 208. The barrier layer 212 may cover a side surface and a bottom surface of the conductive pad 210. The device layer 206 may include active devices, such as transistors and silicon controlled rectifiers, and/or passive devices, such as resistors, capacitors, or inductors. The pad oxide layer 204 may include an oxide material, such as silicon oxide (SiOₓ). The dielectric layer 208 may include a dielectric material, such as silicon oxide (SiOₓ), silicon nitride (SiNₓ), and silicon carbonitride (SiCₓN_{y}). The barrier layer 212 may include a metal barrier material, such as tantalum, tantalum nitride, cobalt, ruthenium, titanium, and titanium nitride. The conductive pad 210 may include a conductive material, such as copper, aluminum, tungsten, tantalum, titanium, titanium nitride, tantalum nitride, and any combination thereof. The active devices and/or passive devices in the device layer 206 may be electrically connected to the conductive pad 210 and the barrier layer 212.

In an embodiment, the pad oxide layer 204 can be formed on the surface 200U of the substrate 200 through a deposition process. The device layer 206 can be formed on the pad oxide layer 204 through a deposition process and an etching process. The dielectric layer 208 can be formed on the device layer 206 through a deposition process. A portion of the dielectric layer 208 can be removed through an etching process, and the conductive pad 210 and the barrier layer 212 are formed in the dielectric layer 208 through a deposition process. The upper surface 210U of the conductive pad 210 may be recessed inward, or alternatively, the upper surface 210U of the conductive pad 210 may be substantially flat and coplanar with the upper surface 208U of the dielectric layer 208. The device layer 206 may be formed in the front-end-of-line (FEOL) process and the back-end-of-line (BEOL) process of the semiconductor manufacturing process.

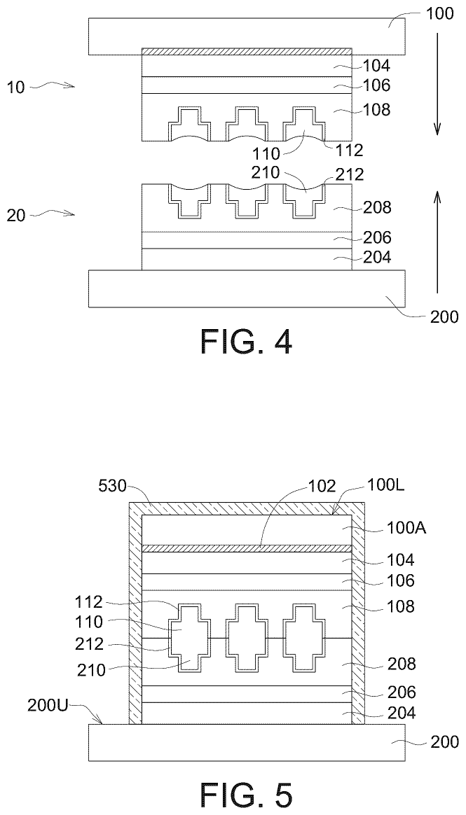

Referring to FIGS. 4 and 5, FIG. 4 shows a schematic view of the structure at one stage of the method for manufacturing the semiconductor bonding structure, and FIG. 5 shows a schematic view of the structure at another stage of the method for manufacturing the semiconductor bonding structure. The semiconductor structure 10 is hybrid bonded to the semiconductor structure 20. In an embodiment, the conductive pad 110 of the semiconductor structure 10 is aligned with the conductive pad 210 of the semiconductor structure 20; then, the semiconductor structure 10 and the semiconductor structure 20 are moved along the directions of the arrows shown in FIG. 4 respectively so that the dielectric layer 108 of the semiconductor structure 10 contacts the dielectric layer 208 of the semiconductor structure 20 and the conductive pad 110 of the semiconductor structure 10 contacts the conductive pad 210 of the semiconductor structure 20; then, the dielectric layer 108 of the semiconductor structure 10 is bonded to the dielectric layer 208 of the semiconductor structure 20 and the conductive pad 110 of the semiconductor structure 10 is bonded to the conductive pad 210 of the semiconductor structure 20 through a solid state bonding technology. For example, the solid state bonding technology can be a fusion bonding technology or a thermal compression bonding technology. In an embodiment, the conductive pad 110 of the semiconductor structure 10 and the conductive pad 210 of the semiconductor structure 20 will re-grow and be bonded to each other during the bonding process, and therefore there is no bonding interface between the conductive pad 110 of the semiconductor structure 10 and the conductive pad 210 of the semiconductor structure 20. After the semiconductor structure 10 is hybrid bonded to the semiconductor structure 20, the conductive pad 110 can be electrically connected to the conductive pad 210.

In this embodiment, the bonding of the semiconductor structure 10 and the semiconductor structure 20 can be understood as a wafer-to-wafer bonding process. The hybrid bonding involves at least metal-to-metal bonding (such as the bonding of the conductive pad 110 and the conductive pad 210) and non-metal to non-metal bonding (such as the bonding of the dielectric layer 108 and the dielectric layer 208). The hybrid bonding technology is different from the traditional bumping technology (bonding technology using bumps). As compared with traditional bumping technology, the hybrid bonding technology can effectively reduce bonding pad pitch, reduce size of bonding pad, and increase the number of bonding pads per unit area. Therefore, the semiconductor bonding structure formed by the hybrid bonding technology has properties such as low thickness, high reliability, high integration density and enabling higher data communication speeds.

After the semiconductor structure 10 is hybrid bonded to the semiconductor structure 20, a dicing process can be performed to remove a portion of the substrate 100, and the remaining portion of the substrate 100 can be defined as the substrate 100A (as shown in FIG. 5). In this embodiment, the dicing process removes the substrate 100 around the doped region 102. In an embodiment, a polishing process can be performed from the back side of the substrate 100 to reduce the thickness of the substrate 100 before the dicing process.

A semiconductor film 530 is formed on the substrate 200. The semiconductor film 530 may cover a side surface of the dielectric layer 108, a side surface of the device layer 106, a side surface of the pad oxide layer 104, a side surface of the substrate 100A, a surface 100L of the substrate 100A, a side surface of the dielectric layer 208 of the semiconductor structure 20, a side surface of the device layer 206 of the semiconductor structure 20, a side surface of the pad oxide layer 204 of the semiconductor structure 20, and a portion of the surface 200U of the substrate 200 of the semiconductor structure 20. The surface 100L of the substrate 100A faces away from the dielectric layer 108. The semiconductor film 530 can include or be made of a semiconductor material, such as silicon, germanium, gallium arsenide, silicon carbide, and gallium nitride. A resistance to a polishing process of the substrate 100/100A can be the same as or substantially the same as a resistance to the polishing process of the semiconductor film 530. That is, the material of the semiconductor film 530 and the material of the substrate 100/100A have the same or similar polishing rate. In an embodiment, the semiconductor film 530 and the substrate 100/100A both include silicon. In an embodiment, the semiconductor film 530 includes or is made of amorphous silicon.

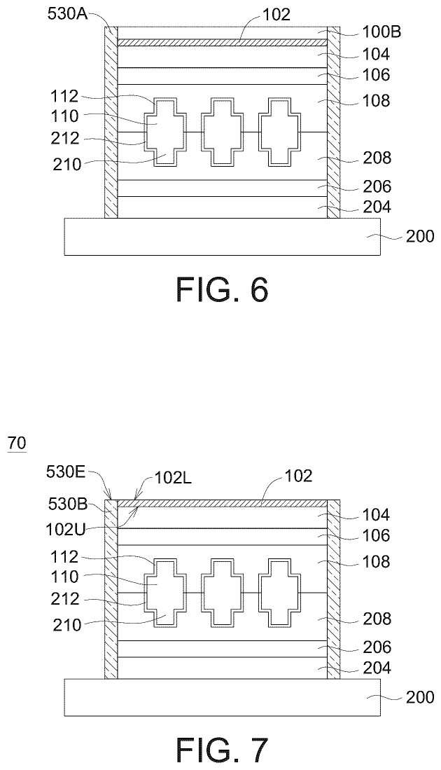

Referring to FIGS. 6 and 7, FIG. 6 shows a schematic view of the structure at one stage of the method for manufacturing the semiconductor bonding structure, and FIG. 7 shows a schematic view of the structure at another stage of the method for manufacturing the semiconductor bonding structure. A portion of the semiconductor film 530 and the substrate 100A are removed to expose the doped region 102 and form a semiconductor bonding structure 70 shown in FIG. 7, and the remaining portion of the semiconductor film 530 can be defined as the semiconductor film 530B. In an embodiment, the substrate 100A and a portion of the semiconductor film 530 on the side surface and surface 100L of the substrate 100A (or can be understood as the top portion of the semiconductor film 530) can be removed through a polishing process to expose a surface 102L of the doped region 102. The surface 102L of the doped region 102 is opposite to the surface 102U of the doped region 102. The polishing process stops when it reaches the doped region 102. Since the resistance to the polishing process of the substrate 100A is the same as or substantially the same as the resistance to the polishing process of the semiconductor film 530, an end surface 530E of the semiconductor film 530B (i.e. the remaining portion of the semiconductor film 530) and the surface 102L of the doped region 102 are at the same height or substantially at the same height the polishing process.

In an embodiment, the step of removing a portion of the semiconductor film 530 and the substrate 100A to expose the doped region 102 includes: performing a mechanical polishing process (including a rough polishing and a finishing polishing) to remove a portion of the semiconductor film 530 on the surface 100L of the substrate 100 and a portion of the substrate 100A to form the structure shown in FIG. 6, the remaining portion of the semiconductor film 530 can be defined as the semiconductor film 530A, and the remaining portion of the substrate 100A can be defined as the substrate 100B; then, performing a chemical-mechanical polishing to remove the substrate 100B and a portion of the semiconductor film 530A on the side surface of the substrate 100B to expose the surface 102L of the doped region 102 and form the semiconductor bonding structure 70 shown in FIG. 7. A thickness of the substrate 100A can be greater than a thickness of the substrate 100B.

Boron doping to the semiconductor material can reduce the polishing rate of the semiconductor material (increase the resistance to the polishing process), so that the polishing rate of the doped region 102 is smaller than the polishing rate of the substrate 100A/100B and the polishing rate of the semiconductor film 530/530A. Therefore, The stop time of the polishing process can be precisely controlled to avoid structural damage caused by over-polishing. The doped region 102 may serve as a polishing-stop layer.

In a comparative example, the semiconductor structure 10 does not include the doped region; after the semiconductor structure 10 is bonded to the semiconductor structure 20, a polishing process is performed to remove the substrate of the semiconductor structure 10. In this comparative example, over-polishing may easily occur during the polishing process since the semiconductor structure 10 does not include the doped region, which results in damage to the pad oxide layer.

In another comparative example, the semiconductor structure 10 does not include the doped region; after the semiconductor structure 10 is bonded to the semiconductor structure 20, a tetraethoxysilane (TEOS) layer is formed to cover the formed structure, the top portion of the tetraethoxysilane layer is then removed by a polishing process to expose the substrate, an etching process is then performed using tetramethylammonium hydroxide as an etchant to remove the substrate and retain the tetraethoxysilane layer originally formed on the side surface of the substrate, and then a chemical-mechanical polishing is performed using tetramethylammonium hydroxide as a polishing aid to remove the tetraethoxysilane layer originally formed on the side surface of the substrate. In this comparative example, damage to the pad oxide layer may be avoided by separately removing the substrate and the tetraethoxysilane layer originally formed on the side surface of the substrate, however, the small size of the tetraethoxysilane layer originally formed on the side surface of the substrate makes it easy to break during the polishing process. Once the tetraethoxysilane layer breaks, the polishing process will cause damage to the pad oxide layer. In addition, in this comparative example, tetramethylammonium hydroxide is used in etching process and polishing process. Tetramethylammonium hydroxide is toxic and cost for treating tetramethylammonium hydroxide is high, which can easily cause biological and environmental hazards.

In the method for manufacturing a semiconductor bonding structure according to the present disclosure, a doped region is formed in the substrate, the doped region can be functioned as a polishing-stop layer so as to precisely control the stop time of the polishing process and avoid structural damage. Moreover, the manufacturing method according to the present disclosure does not require the use of tetramethylammonium hydroxide, which can improve process safety, reduce process complexity and reduce costs.

While the disclosure has been described by way of example and in terms of the exemplary embodiment(s), it is to be understood that the disclosure is not limited thereto. On the contrary, it is intended to cover various modifications and similar arrangements and procedures, and the scope of the appended claims therefore should be accorded the broadest interpretation so as to encompass all such modifications and similar arrangements and procedures.

What is claimed is:

1. A method for manufacturing a semiconductor bonding structure, comprising:
forming a first semiconductor structure, comprising:
introducing boron into a first substrate to form an doped region in the first substrate;
forming a first dielectric layer above the first substrate; and
forming a first conductive pad in the first dielectric layer;
forming a second semiconductor structure, comprising:
forming a second dielectric layer above a second substrate; and
forming a second conductive pad in the second dielectric layer; and
hybrid bonding the first semiconductor structure and the second semiconductor structure, wherein the first conductive pad is attached to the second conductive pad, and the first dielectric layer is attached to the second dielectric layer.

2. The method according to claim 1, further comprising:
forming a semiconductor film on the second substrate after the first semiconductor structure is hybrid bonded to the second semiconductor structure.

3. The method according to claim 2, wherein the semiconductor film and the first substrate comprise silicon.

4. The method according to claim 3, further comprising:
removing the first substrate and a portion of the semiconductor film to expose the doped region.

5. The method according to claim 4, wherein an end surface of the remaining portion of the semiconductor film and a surface of the doped region are substantially at the same height after removing the first substrate and the portion of the semiconductor film.

6. The method according to claim 1, further comprising:
forming a semiconductor film to cover a side surface of the first dielectric layer, a side surface of the second dielectric layer, a side surface of the first substrate, and a surface of the first substrate facing away from the first dielectric layer.

7. The method according to claim 6, wherein a resistance to a polishing process of the first substrate is substantially the same as a resistance to the polishing process of the semiconductor film.

8. The method according to claim 7, further comprising:
removing the first substrate and a portion of the semiconductor film on the side surface of the first substrate and the surface of the first substrate to expose the doped region.

9. The method according to claim 1, further comprising:
forming a first pad oxide layer between the doped region and the first dielectric layer; and
forming a second pad oxide layer between the second substrate and the second dielectric layer.

10. The method according to claim 1, further comprising:
forming a first barrier layer between the first conductive pad and the first dielectric layer; and
forming a second barrier layer between the second conductive pad and the second dielectric layer.

11. The method according to claim 1, wherein the doped region comprises boron and silicon.

12. The method according to claim 1, further comprising:
removing the first substrate through a chemical-mechanical polishing process to expose the doped region.
